(19) United States
(12) Patent Application Publication
(10) Pub. No.: US 2007/0108459 A1
(43) Pub. Date: May 17, 2007

(54) Methods of Manufacturing Light Emitting Devices

(75) Inventor: Zhenghao Jason Lu, Sunnyvale, CA (US)

Correspondence Address: ZHENGHAO JASON LU, 1129 ROBIN WAY, SUNNYVALE, CA, 94087, US

(73) Assignee: Enfocus Engineering Corp, Sunnyvale, CA (US)

(21) Appl. No.: 11/279,490

(22) Filed: Apr. 12, 2006

Related U.S. Application Data
(60) Provisional application No. 60/672,110, filed on Apr. 15, 2005.
(60) Provisional application No. 60/721,645, filed on Sep. 29, 2005.

(51) Int. Cl. H01L 33/00

(52) U.S. Cl. 257/98

(57) ABSTRACT

Light emitting devices (LED) and methods of fabricating such, comprising a substrate, a light extraction structure, and an emitting layer sandwiched between a plurality of semiconductor layers of the first and the second type. The said extraction structure is processed into preferred geometric shapes using preferred methods.

### FIELD OF INVENTION

The present invention is in the field of light emitting devices such as a light emitting diodes (LEDs) or organic light emitting diodes (OLEDs), and more particularly to the enhanced light escaping or extraction from emitters.

### BACKGROUND ART

As illustrated in FIG. 1, a solid state light emitting device (LED) typically consists of a light emitting layer, 13, sandwiched between an electron injection layer (n-type) and a hole injection layer (p-type), 12 and 14. The LED stack (12 through 14) is attached to a supporting substrate, 10, either in a n up (14 is n-type), or more commonly, a p up (14 is p-type) configuration. The substrate may either be the natural growth substrate or mounted later using wafer bonding techniques. An intermediate layer, 11, is commonly formed between the LED stack and the substrate, being a buffer layer, multi-layer reflector, or a metal adhesion and/or reflector. The LED stack may face up as in most common LEDs, or may face down in the case of a flip chip where emission is reflected upward by a reflector and exits through the substrate. Electrical terminals are connected to n and p layers through metal bond pads, and often through the substrate when it is electrically conductive. A diced chip from the processed device is then mounted in a package which usually consists of a reflective cup, a lens cap, and index matching encapsulation which may also include phosphors for light in white or other colors.

The electrical to optical power conversion efficiency can be viewed as a product of internal quantum efficiency (IQE), energy state efficiency (average photon energy divided by applied voltage), and light extraction efficiency (LEE). The LEE is due to the fact that most of the semiconductor materials have large index of refraction. As a result, the critical angle at which emitted light experience total internal reflection at the exit surface is quite small, as depicted by the light rays enclosed between 21 and 22 in FIG. 2. Large amount of emitted rays are trapped inside the device, as depicted by 25, 26, 27, lost to absorption in multiple reflections. Therefore, methods to improve LEE have resulted in significant advances in the state-of-the-art LEDs. For example, inventions on transparent GaP substrate (TS) to replace absorbing GaAs substrate for InAlGaP LEDs, chip shaping in TS-InAlGaP LEDs and InAlGaN on SiC LEDs, and use of thick reflective metal layers in flip chip designs or in wafer-bonding designs. Despite these advances, a factor of two or more in improvement of LEE remains to be a severe challenge for manufacturers to reach the ideal goal of unity. Furthermore, one common disadvantage of these techniques is that they require strenuous mechanical processing, and suffer from mechanical damages and adhesion issues. These processes are hard-to-control and suffer yield and throughput problems, thus, resulting in high manufacturing cost.

In U.S. Pat. No. 6,091,085, Lester disclosed several interesting methods to enhance the LEE of GaN-based LEDs. The first method involves roughen the front surface of the sapphire substrate before growth of GaN takes place by mechanical scratching and grinding or simple grow on incompletely polished substrates, or by conventional lithography to define openings on photoresist and then transfer to the said substrate by etching. The second method uses lateral growth of GaN through patterned SiO₂ on grown LED structures. This leads to faceted pyramids, which according to the inventor, would couple more light out. The third method involves etching into GaN to form trenches, which are subsequently filled by a lower index material such as SiO₂. Acting like light pipes, the protrusions then extract light from LED stack underneath. The fourth method involves in a flip chip design where a reflective metal is deposited on microscopic pits or depressions from GaN surface formed during growth under certain conditions. According to the invention, the metal on facets of the hexagonal shaped pits would enhance light extraction by reflection the incident light. These methods are based on readily available technologies and are conceivably easier to implement. However, to our knowledge, none of these methods are adopted by LED manufacturers since their disclosure in 1998.

### SUMMARY OF THE INVENTION

An aspect of the present invention provides improved light extraction from light emitting devices. It is a further objective of the present invention to replace hard-to-control manufacturing process with more mature processes, thereby, improving yield and reducing manufacturing cost.

According to the present invention, a light emitting device comprises a substrate, a light emitting layer sandwiched between a plurality of layers of the first type and a plurality of layers of the second type. Electrical injection is provided by connecting electrical terminals to the first and the second types.

In one embodiment of the invention, the top layer of the first type is light extractor in preferred geometries where light exit. When the conductivity of the first type is insufficient for uniform current injection, a contact layer and a transparent conducting layer are deposited on the extractor.

In a second embodiment of the invention, an extraction structure is formed between a transparent substrate and the LED stack. A reflector is formed on the LED stack, which is mounted facing down in a flip chip configuration. Light exits the device from the substrate side.

In a third embodiment of the invention, the device is in a flip chip configuration where light is reflected by a reflector and extracted from the transparent substrate which is process into preferred extraction structure.

In a fourth embodiment of the invention, an extractor is formed on top of the first type as described in one of the first four embodiments, and a reflective layer with low absorption is inserted between the bottom of the second type and the substrate.

The fifth and sixth embodiment of the invention, are variations of the third and fourth embodiments, respectively, with side walls of the chip processed to preferred angles with respect the to growth surface.

### BRIEF DESCRIPTION OF THE DRAWINGS

FIG. 1 is the cross section of a generalized conventional light emitting device

FIG. 2 illustrates the light extraction zone and light trapped in a conventional light emitting device.

FIG. 3 illustrates an exemplary cross sectional veiw of a preferred embodiment of the present invention.

FIG. 4 illustrates the exemplary operation of LEE enhancement, in accordance with the preferred embodiment of the present invention.

FIG. 5 illustrates top view of an extraction structure and its variations, in accordance with a preferred embodiment of the present invention.

FIG. 6 illustrates a cross sectional view of the device structure with metal contacts, in accordance with a preferred embodiment of the present invention.

FIG. 7 illustrates the relative IEE improvement with extractor as a function of the extractor angle for an InAlGaN chip using a preferred embodiment.

FIG. 8 illustrates the relative IEE improvement with extractor as a function of the extractor angle for an InAlGaP chip using a preferred embodiment.

FIG. 9 illustrates a cross sectional view of an alternative embodiment of the present invention.

FIG. 10 illustrates a cross sectional view of an alternative embodiment of the present invention.

FIG. 11 illustrates a cross sectional view of an alternative embodiment of the present invention.

FIG. 12 illustrates a cross sectional view of an alternative embodiment of the present invention.

FIG. 13 illustrates a cross sectional view of an alternative embodiment of the present invention.

FIG. 14 illustrates a cross sectional view of an alternative embodiment of the present invention.

FIG. 15 illustrates a cross sectional view of an alternative embodiment of the present invention.

FIG. 16 illustrates a cross sectional view of an alternative embodiment of the present invention.

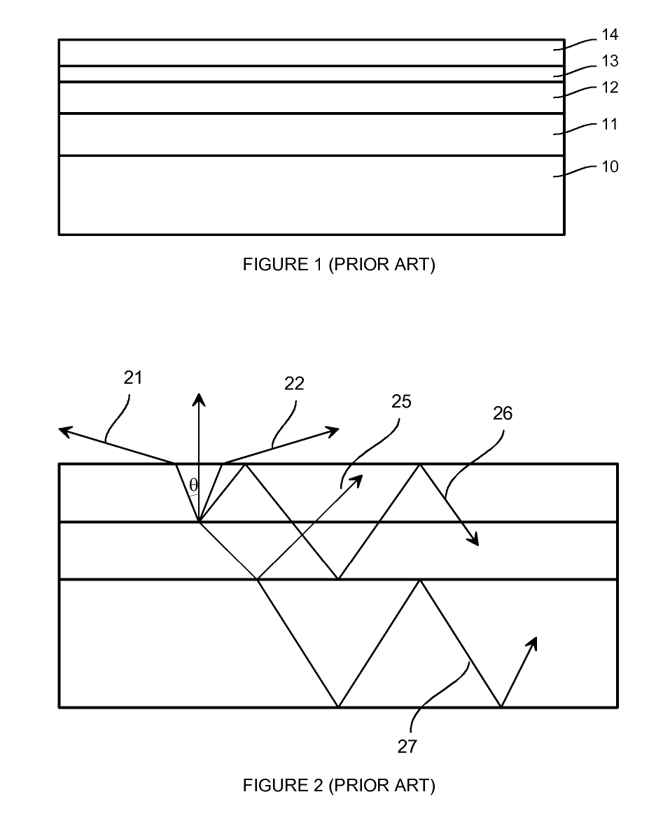

### DETAIL DESCRIPTION OF THE INVENTION

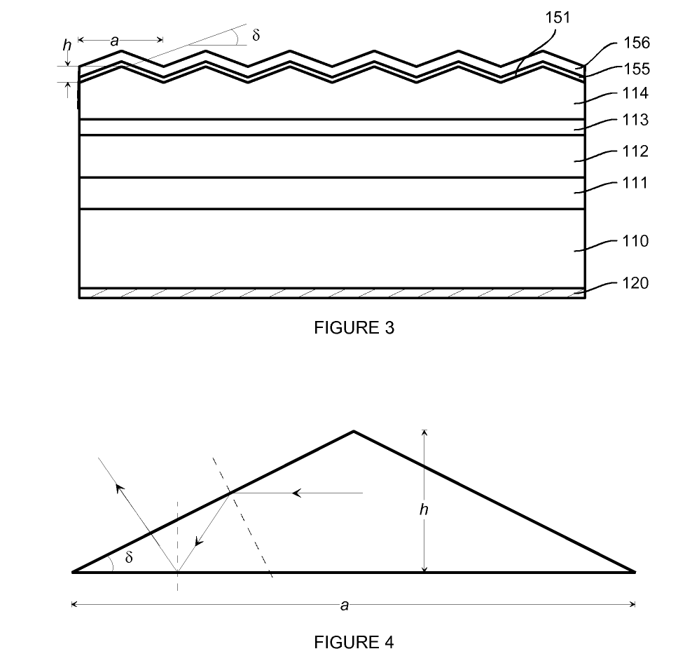

An exemplary cross sectional view of a preferred embodiment of the present invention for light emitting device (LED) is shown in FIG. 3. The LED stack (112, 113, 114) and features from this invention (150, 151, 155, 156) are attached to a suitable substrate 110, which, by way of example and not limitation, can be sapphire, SiC, GaN, AlN, GaP, GaAs, InP, Si or Ge. The LED stack can be based on many material systems with index of refraction >1.5, such as InAlGaN, InAlGaP, AlInGaAs, InGaNAs, AlInGaSb with composition ranging from 0 to 100%. The light emitting layer, 113, is sandwiched between an n-type layer, 112, and a p-type layer, 114, to form a p-n junction, although the order of the n-type and p-type layers may be reversed. The n-type and p-type layers may each contain a plurality of layers of the same conduction type. Electrical contacts, which are omitted in drawings for the sake of clarity (unless they are instructive to this invention regarding light extraction efficiency (LEE) enhancement) are attached to p and n layers, respectively, for electrical injection. Electrons and holes are injected into the emitting layer where they recombine radiatively to generate photons. Some of light rays may come out of the top surface subject to Fresnel law, while others are reflected between the top and bottom surfaces and come out from the top and side surfaces, after losing some to absorption in various layers and surfaces. The chip is preferably packaged in a LED enclosure comprising of an optical lens, a lead frame with or without a protective circuitry, a reflective cup. The enclosure is filled with an encapsulant, such as, for example, epoxy or silicone, with index of refraction preferably as close as possible to that of the top layer. In some applications, a phosphor material is coated on the chip or dispersed in the encapsulant to convert part or all of the light from LED to a desired color. In a flip chip configuration, the LED stack is preferably mounted facing down on a support with electrical circuitry and good thermal dissipation properties. Light comes out of the substrate side. In the description, we shall follow a convention that light exit the package in the upward direction unless specifically described otherwise.

The substrate may be the natural substrate used in the deposition or epitaxial growth of the LED stack. Or it may be a substitute attached to the LED stack using wafer bonding techniques, with or without using a metallic interlayer to reflect light rays and/or provide electrical contact. The substrate need not be electrically conductive, such as in the case of a sapphire substrate. The reflector, 120, shown in FIG. 3, is preferably a high reflectivity, low loss metallic film, such as Ag, Al, Au, or embedded in a multilayer alloy such as, by way of example, and not limitation, Ni, Ti, W, Pd, Pt, Ta and their nitrides for better ohmic contact, adhesion, barrier to diffusion. Alternatively, the reflector 120 can be the bottom of a reflector cup, attached with low absorption adhesive such as, by way of example, and not limitation, clear epoxy or silver filled epoxy.

In a preferred embodiment of this invention, the top surface of layer 114 is processed into geometrically shaped extraction structures or extractors, 151, to enhance LEE. An explanation of how an extractor functions is depicted by way of simplified example in FIG. 4. The characteristic angle δ, named in this invention as the extractor angle, is chosen to be close to the critical angle, θ_{c}, such that rays within the extraction zone with respect to the nature growth surface can directly exit. A ray at a large angle is reflected by the pyramid side walls. With each pass, its incident angle with respect to the side wall is reduced by δ. For δ˜20°, rays at large angle can be reduced below θ_{c} in a few passes. An array of these extraction structures covering the exit surface of a device can enhance LEE significantly.

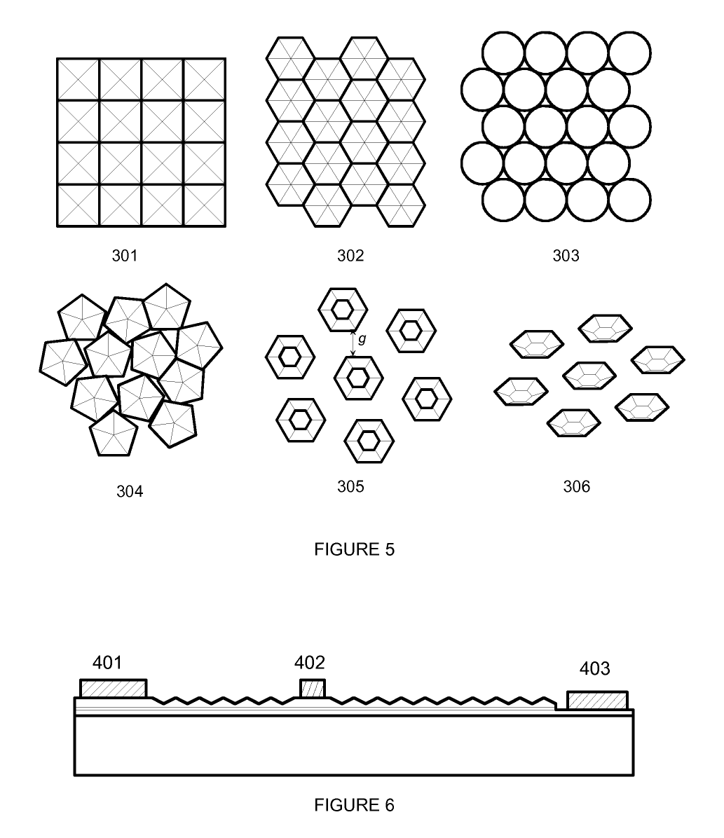

FIG. 5 shows top view of an extraction structure and its variations in accordance with a preferred embodiment. Layout 301 comprises tetrahedral pyramids. Layout 302 comprises hexagonal pyramids. Layout 303 comprises cones. Layout 304 shows quasi randomly arranged pentagons. Layout 305 shows truncated pyramids that are separated by gaps. Layout 306 is a side view from the top of inverse truncated pyramids which are indented into layer 114. An extraction structure is characterized by the side angle, δ, the base length, a, the height, h, and the gap between each structure, g. The structure is shown as symmetrical for the sake of clarity to simplify the illustration, though they may actually be different in practice. For example, they can be tilted pyramids.

The gap determines the surface coverage of the extraction structures. The efficiency for some of the extraction structures is sufficiently high such that LEE does not drop significantly at reduced coverage. This allows high degree of design flexibility to meet processing requirement, such as incorporation of contact fingers and transparent conducting layer (TCL). The extraction structures can be arranged periodically according to their natural symmetry or randomly to minimize wave guiding.

For a larger extractor angle, the height of a full pyramid increases as a/2 tan δ. Since the lateral dimension of the extraction structure is limited by the resolution and smoothness of the photolithography, large δ may require growth of a very thick film for the extraction structure. To solve this problem, we also studied truncated extraction structures. When the height is less than the full pyramids (h<a/2 tan δ), the pyramid or cone is truncated. Truncated extractors also have the advantage of keeping large portion of as grown surface for electrical contact and current spreading purposes. We found that although LEE is the highest in embodiments of the present invention with full extractors, the LEE for in embodiments of the present invention with truncated extractors does not drop significantly. This can be advantageous for the design and manufacturing of LEDs with extraction structures.

The height of the extraction structure, h, is one of the determining factors for an optimal thickness for layer 114. Layer 114 is chosen to be relatively transparent to light emitted from the active region, i.e., its absorption bandgap is larger than the photon emission energy. However, there is non-negligible amount of absorption at larger thickness, causing loss of efficiency. Other practical factors such as growth time, etching time, and effect on underlying layers during high temperature growth of layer 114 also put an upper limit on its thickness. On the other hand, for an effective optical extraction, extractor height should be at least a fraction of the wavelength in the material. For example, for blue emission from InAlGaN LEDs, the extractor should be at least 0.02 μm (about tenth of the wavelength in GaN). Other practical considerations such as resolution of the lithographic methods described later and safeguard for the extractors not penetrating layer 114 may also set a limit for extractor height in some applications. Combining these considerations, the extractor thickness should typically be in the range of 0.01 to 100 μm to be practical. More preferably, however, this thickness should be in the range of 0.02 to 10 μm. The optimal thickness is selected using aforementioned relation: h ˜a/2 tan δ when lateral size or extractor angle is small, or use truncated pyramids when the result from such calculation is too large.

Preferred methods to produce these extraction structures are based on photo lithography, which are mature technologies, allowing high yield and throughput, and consequently, lower manufacturing cost. One of the preferred methods is to use reflow photoresist technique used in micro lens manufacturing. An array of square, hexagonal or circular shaped photoresist pattern is generated using this process. During reflow, surface tension causes the edges to thin down, while the center to become thicker. After a hard bake at high temperature, they form the desired shapes shown in FIG. 5. Using dry-etch techniques such as Inductively Coupled Plasma (ICP) or Reactive Ion Etch (RIE), the photoresist shape is transferred to the underlying layer 114 in all three dimensions. Another preferred method starts with a gray scale photo mask. During exposure, photoresist under darker regions of the mask pattern receives lower dosage. After developing the exposed photoresist, the thickness of the residual photoresist varies proportional to the gray scale of the mask, thus, generating the desired shapes shown in FIG. 5. Using aforementioned dry etch processes, the photoresist shape is transferred to the underlying layer 114. Those skilled in the art will readily recognize a multiplicity of other suitable techniques to produce the present extraction structures in light of the teaching of the present invention.

It is worth to note that, in the preferred embodiment, regions for thick metal bond pads and contact fingers preferably do not contain these geometrical shaped extraction structures. This is especially important when a contact layer, for example, a heavily doped material with good electrical conductivity, is grown on top of 114 to reduce contact resistance. Etching of the contact layer underneath the metal contact would cause poor electrical contact. In addition, surface roughness and surface texturing under metallization tend to disrupt the continuity and adhesion of the metallization, resulting in poor electrical performance, lower yield and degradation over usage (or poor lifetime). Thus, maintaining a planar surface underneath the metallization is critical to achieve low operation voltage, high manufacturing yield, and good long term reliability. In the application of the present invention, the photo mask for the extraction structure is designed to leave photoresist on the bond pad regions intact to prevent etching of the underlying layer. An exemplary contact arrangement of is depicted in a cross sectional view of the device in FIG. 6, where regions with wiggly surface represent extraction structures; 401 and 403 are bond pads for the two electrical terminals; 402 is a contact finger which spreads from a bond pad to distribute electrical current uniformly across the chip.

If electrical conduction of layer 114 is sufficient for the application, such as thick n-type GaN layer, or thick p-type GaP layer, additional layers 155, 156 are not necessary. However, when the electrical conduction of layer 114 is insufficient for the application, a contact layer, 155, and a transparent conducting layer (TCL), 156 may be necessary to spread the current uniformly. The preferred method for contact layer 155 is to epitaxially regrow a thin and highly doped material, for example, InGaN for GaN system, InGaAs or GaAs for AlGaAs, InGaP, InAlGaP systems. Subsequently, a TCL such as a thin Ni/Au layer, or an indium tin oxide (ITO) or other transparent conducting oxides (TCO) is deposited, by way of example, and not limitation, by using e-beam sputtering process or other deposition processes.

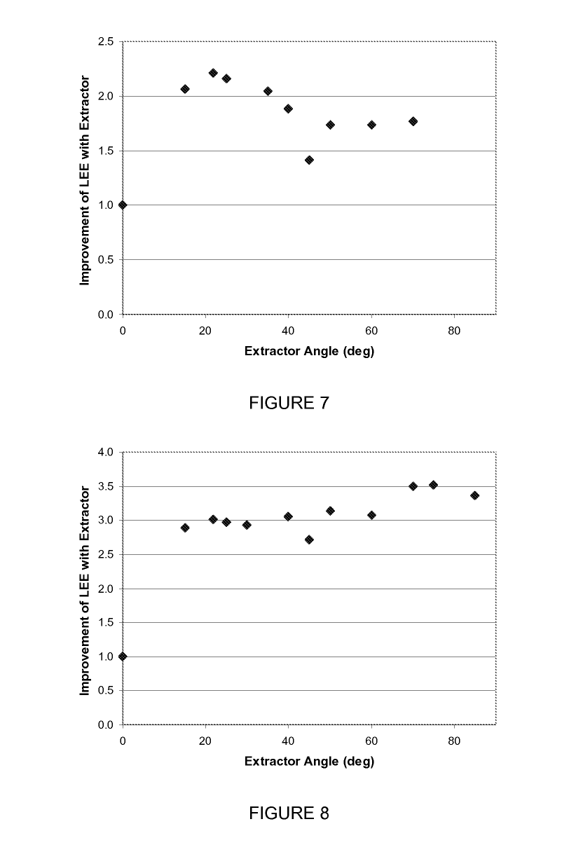

The enhancement of LEE for a bare (without index matching encapsulation) InAlGaN chip on sapphire emitting at 460 nm using a ray trace calculation is shown in FIG. 7. Relative LEE improvement is seen for LEDs with extractors as compared to conventional flat surface LEDs. The LEE is more than doubled with β at ˜22°, making the bare chip as efficient as LEDs packaged with index matching encapsulation (index ˜1.48). With silicone or epoxy encapsulation, the LEE efficiency is further enhanced by 30% for devices with extractors. The enhancement falls off at larger angles. It is worthwhile to note that a small extractor angle is beneficial to maintain continuity for layers on top of the texture and to ease the wetting of encapsulation and avoid air bubble trapped at steep corners.

Similar LEE enhancement is observed for InAlGaP based LEDs using the preferred embodiment. The InAlGaP LED stack is attached to a transparent conducting GaP substrate using known wafer bonding technology. The growth substrate, typically, but not limited to, GaAs which absorbs emitted light strongly, is removed and replaced with a GaP substrate. It is also possible to grow InAlGaP directly on GaP substrate using optimal buffer growth techniques, which will be readily recognized by those skilled in the art. A thick GaP window layer is formed on the InAlGaP LED for epi side up applications. Extractors are formed on the thick GaP layer. Results for 630 nm emission without encapsulation are shown, by way of example, in FIG. 8, where it shows similarly significant enhancement on LEE as seen for InAlGaN LEDs. At angles >70°, the LEE increases further. With index matching encapsulation, an additional 20% LEE improvement is observed.

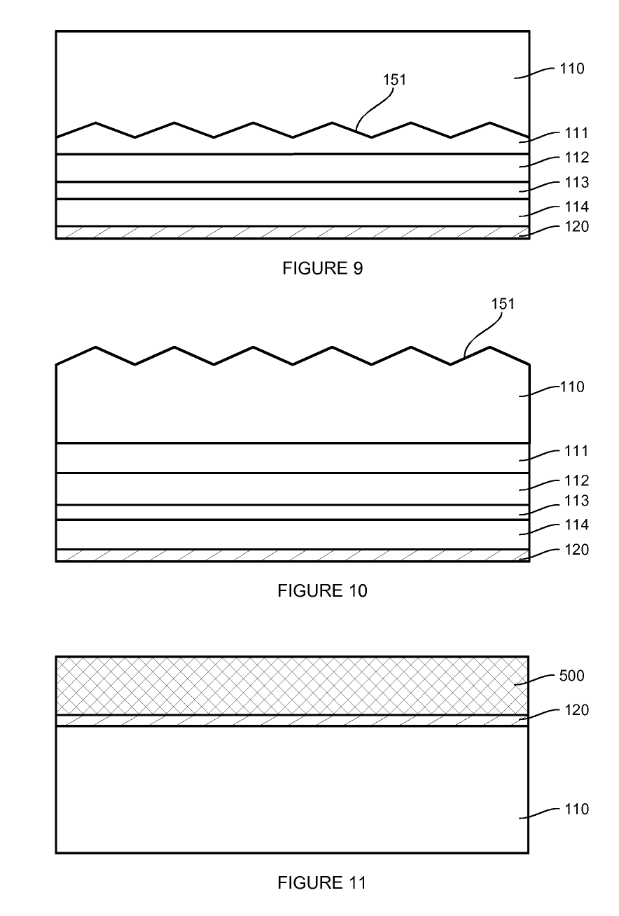

A second embodiment of this invention is shown in FIG. 9, where extractors 151 are formed between the substrate and the LED stack. This can be achieved by forming extraction structures on the substrate before growth preferably using aforementioned methods. As the buffer layer 111 grows thicker, the growth front planarizes under conditions known to those skilled in the art. LED stack (112, 113, 114) is subsequently grown. A high reflective metallization stack, 120, is deposited and processed to form electrical contact while acting as a reflector. An application of this embodiment is analyzed for an InAlGaN flip chip on sapphire as a representative example of a multiplicity of other known and suitable combinations. Extractors 151 minimize reflections at GaN and sapphire interface. Since sapphire has an index close to that of the encapsulant (1.7 and 1.48 respectively), light can traverse sapphire/encapsulant/air interfaces with minimal Fresnel reflection. It is noted that under optimal growth conditions, pre-patterned substrate may also lead to enhancement of IQE by annihilating threading dislocations. Improvements of up to 225% for bare chips and 71% for encapsulated LED lamps at extractor angle δ˜22°, as compared to LEDs with planar GaN/sapphire interface.

A third embodiment of this invention is combined with epi-side-down designs. The top surface of the LED stack is coated with highly reflective metal contact layers and mounted “face down” as shown in FIG. 10. A relatively transparent substrate, 110, such as SiC for a InAlGaN LED or GaP for a InAlGaP LED, is used in this type of LEDs. Light emitted from the active region is reflected by the bottom reflector towards the top surface of the substrate, which has extraction structure 151 to assist the light extraction. In many applications, a similar or higher improvement of LEE can be obtained as in the first embodiment, especially when the reflectivity of the metal contact layer is over 90%.

A fourth embodiment of this invention is shown in FIG. 11 as a variation of the first embodiment. The LED stack and extractor (111 through 156), now labeled as a block, 500, is attached to a highly reflective metal layer instead of a substrate. Metal bonded LEDs are of this type, where the LED stack is bonded to a Si or other suitable substrate through a reflective metal stack. The growth substrate is subsequently removed. The reflector reflects light emitted backward towards the exit surface which contains an extractor to help light escape the device. Organic LEDs (OLEDs) can also be made of this type of structure to take advantage of enhanced LEE. In an OLED device, organic films are deposited or coated on a supporting membrane covered by reflective metal layers. A TCL layer, such as, for example, appropriately doped ITO, is then deposited as the top contact layer and subsequently processed into extraction structure according to this embodiment.

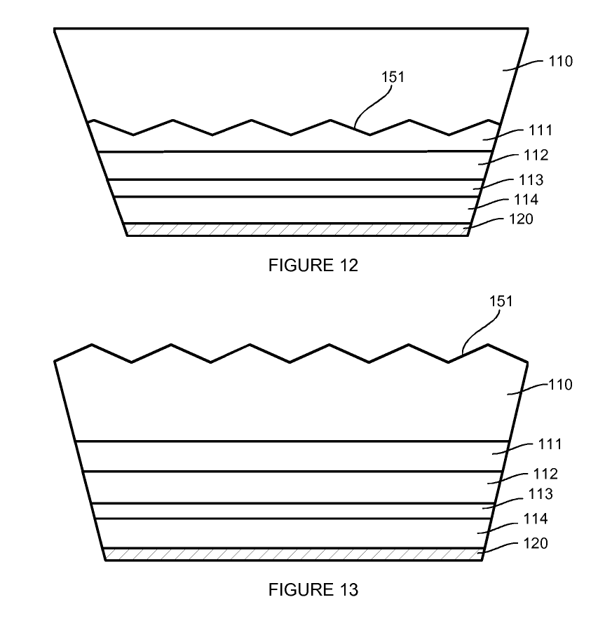

A fifth and sixth embodiment of this invention, illustrated in FIGS. 12 and 13, respectively, are a variation of the second and third embodiment with side wall machined to an angle that is not normal to the top or bottom surfaces, also known as chip shaping. Chip shaping reduces multiple reflection, thus, improves the LEE. The preferable side wall angle is between 20° to 70° for optimal LEE.

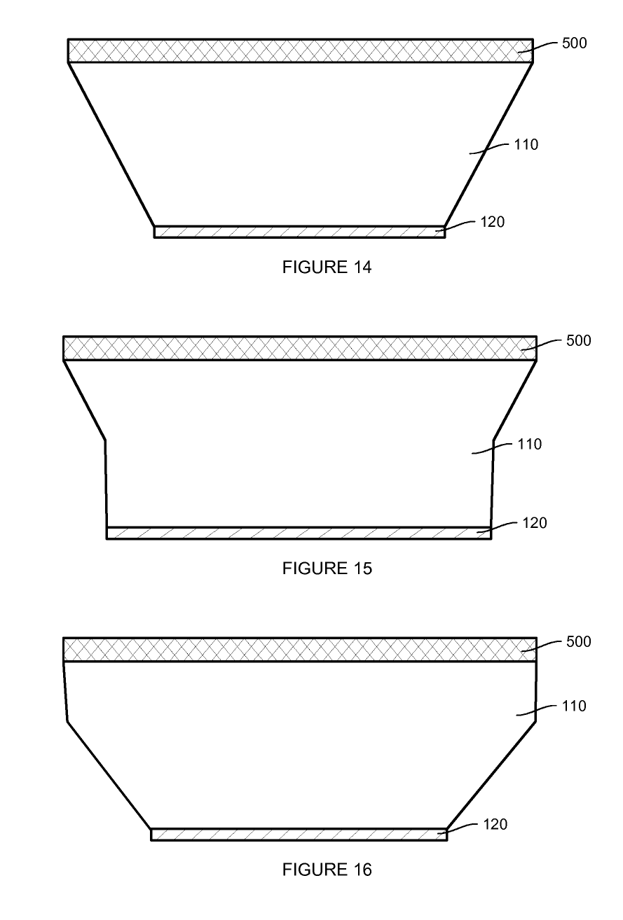

FIGS. 14-16 illustrate more variations of the first embodiment with chip shaping of the side walls. The LED stack and extractor (111 through 156) are labeled as a block, 500.

### EXAMPLES

Some exemplary manufacturing techniques for some embodiments of the present invention will now be described to enable those skilled in the art to readily adapt the teachings of the present invention into a multiplicity of alternative material combinations and known processing techniques.

InAlGaN p-up LED on sapphire, First Embodiment:
1) Epi growth using Metal Organic Chemical Vapor Phase Deposition (MOCVD):
   a) Start with sapphire substrate, 110.
   b) Grow nucleation layer, GaN or AlN, or multilayer of InAlGaN/GaN, 10 to 100 nm thick.
   c) Grow a thick GaN buffer layer, 111, 0.5 to 5 μm, undoped or lightly doped with Si.
   d) Grow n-type GaN, 112, 0.5-5 μm, doped with Si.
   e) Grow InGaN/GaN multiple quantum wells (MQW) as the active region, 113, for light emission, 2 to 20 pairs, InGaN quantum wells (QW) are ˜2-4 nm thick, indium composition is controlled by growth temperature and trimethylindium flow rate to achieve targeted emission wavelength.
   f) Grow p-type GaN or InAlGaN, 114, 0.05 to 1 μm thick, doped with Mg.
   g) Grow contact layer, heavily doped p-type GaN or InGaN. In some device configurations, a heavily doped tunneling junction is grown, instead of a simple contact layer, to allow selection of more appropriate TCL materials such as an ITO layer.
   h) Controlled annealing during cool down to remove hydrogen passivation and to activate Mg dopant.
2) Deposit Ni/Au or ITO TCL on p-type surface.
3) Using one of the preferred methods described in the first embodiment to produce extraction structure, 151. The photo mask is designed to make hole-like extraction structure to allow a connected network of TCL remained for current spreading. Region for the p-type bond pad and current spreading fingers is also protected by photoresist during dry-etch of the extraction structure.
4) Form p metal bond pad and contact fingers.
5) Dry etch to reach n-type layer 112 using n-contact mask.
6) Form n metal bond pad.

Typically, for commercial products, processed wafers will subsequently go through testing, lapping (thinning down the substrate), scribe and break, sorting onto tape according to their performance characteristics before shipping to packaging manufactures. These steps will be omitted in examples hereafter (as they are well known to those skilled in the art) unless some of them require considerations specific to this invention.

InAlGaN on sapphire with regrown contact layer, First Embodiment:
1) Epi growth process is similar to previous example.
2) Using one of the preferred methods described in the first embodiment to produce extraction structure, 151 on layer 114.
3) Reload processed wafers back to MOCVD reactor to regrow a contact layer for p-type layer 114. The contact layer is a heavily doped p-type GaN or InGaN. In some device configurations, a heavily doped tunneling junction is grown, instead of a simple contact layer, to allow selection of more appropriate TCL materials such as an ITO layer.
4) Deposit Ni/Au TCL by using, for example, a thermal evaporator, 0.005 to 0.1 μm thick to maximize transmission. In some device configurations, an ITO TCL is deposited by using, for example, e-beam sputtering process.
5) Dry etch to reach n-type layer 112 using n-contact mask.
6) Deposit bond pad metals to form bond pads. When the metallization materials for p-type and n-type are different, a separate deposition process is used for each type.

InAlGaN on Sapphire Flip Chip, Second Embodiment
1) Using one of the preferred methods described in the first embodiment to produce extraction structure, 151, on a sapphire substrate, 110. In this case, the extraction structure covers the entire wafer since there is no electrical contact through substrate.
2) Epi growth of AlInGaN LED:
   a) Grow nucleation layer, GaN or AlN, or multilayer of InAlGaN/GaN, 10 to 100 nm thick.
   b) Grow a thick GaN buffer layer, 111, 0.5 to 10 μm using conditions favor planar growth.
   c) Grow n-type GaN, 112, 0.5-5 μm, doped with Si.
   d) Grow InGaN/GaN multiple quantum wells (MQW) as the active region, 113, for light emission, 2 to 20 pairs, InGaN quantum wells (QW) are ˜2-4 nm thick, indium composition is controlled by growth temperature and/or TMIn flow rate to achieve targeted emission wavelength.
   e) Grow p-type GaN or InAlGaN, 114, 0.05 to 1 μm thick, doped with Mg.
   f) Grow contact layer, heavily doped p-type GaN or InGaN. In some device configurations, a heavily doped tunneling junction is grown, instead of a simple contact layer, to allow selection of more appropriate metallization system for optimal trade off between reflectivity and contact resistance.
   g) Controlled annealing during cool down to remove hydrogen passivation and to activate Mg dopant.
3) Deposit p-metal reflector, 120, which is a multi layer metallization to achieve high reflectivity, low contact resistance and good stability during storage and operation.
4) Etch through LED stack to reach n-type GaN and subsequently define n-metal bond pad using lithographical processes.

Note, a flip chip is mounted epi side down. Light is collected through the substrate side.

InAlGaP on GaP, First and Third Embodiment:
1) Epi growth of InAlGaP LED on GaAs
   a) Start with GaAs substrates
   b) Grown n-type GaAs buffer, 110, 0.01 to 1 μm.
   c) Grow InGaP/GaAs etch stop structure to allow selective removal of GaAs and stop at the next layer at a later time.
   d) Grow InAlGaP attachment layer, 0.001 to 0.1 μm.
   e) Grow n-type AlInP, 112, 0.2-2 μm.
   f) Grow InAlGaP multiple barrier/well structures as the active region, 113, for light emission, where barrier Al composition is fixed at ˜60% and well Al composition is varied to achieve targeted emission wavelength.
   g) Grow p-type AlInP layer, 114, 0.5 to 2 μm thick.
   h) Grow p-type GaP window layer, 114′, 1-15 μm thick.
2) Glue p-type side to a temporary substrate.
3) Selectively etch off the GaAs and InGaP/GaAs etch stop structure to stop at InAlGaP attachment layer.
4) Wafer bond the InAlGaP stack on a n-type GaP substrate.
5) Form n metal bond pad on n-GaP substrate.
6) Form p metal bond pad and contact fingers on p-GaP window.
7) Using one of the preferred methods described in the first embodiment to produce extraction structure, 151 on p-type GaP window.

Note, the extraction structure can also be made on the n-type GaP substrate surface according to the third embodiment. A metal reflector stack is deposited on p-type GaP surface to act as reflector and electrical contact. Chip is mounted with p side facing down.

InAlGaP on GaP, First Embodiment and Third Embodiment:
1) Epi growth of InAlGaP LED on GaAs: similar to previous example, except that a n-type InAlGaP extraction layer is added between the AlInGaP/GaAs etch stop structure and the n-type AlInP layer. The extraction layer is in the range of 0.1 to 5 μm thick and the Al composition is 40-70% to minimize light absorption.
2) Bond the GaP side of the wafer to a p-type doped GaP using wafer bonding processes.
3) Selectively remove the GaAs substrate and AlInGaP/GaAs etch stop structure to stop at InAlGaP extraction layer.
4) Form p-metal contact pad on GaP side.
5) Form n-metal contact pad and fingers on n-type InAlGaP extraction layer.
6) Using one of the preferred methods described in the first embodiment to produce extraction structure, 151 on n-type InAlGaP extraction layer.

Note, the extraction structure can also be made on the p-type GaP substrate surface according to the third embodiment. A metal reflector stack is deposited on n-type InAlGaP surface to act as reflector and electrical contact. Chip is mounted with n side facing down.

InAlGaP on Si, Fourth Embodiment:
1) Grow InAlGaP LED on GaAs same as described in previous example.
2) Deposit metal stack on p-type GaP window to act as a reflector and electrical contact
3) Deposit metal adhesion layer on a conductive Si wafer
4) Metal bond the LED wafer and the Si wafer.
5) Selectively remove the GaAs substrate and InGaP/GaAs etch stop layers.
6) Form metal contact on Si side.
7) Form n-metal contact pad on the n-type InAlGaP extraction layer.
8) Using one of the preferred methods described in the first embodiment to produce extraction structure, 151 on n-type InAlGaP extraction layer.

Having fully described at least one embodiment of the present invention, other equivalent or alternative methods of implementing light emitting devices according to the present invention will be apparent to those skilled in the art. The invention has been described above by way of illustration, and the specific embodiments disclosed are not intended to limit the invention to the particular forms disclosed. The invention is thus to cover all modifications, equivalents, and alternatives falling within the spirit and scope of the following claims.

What is claimed is:

1. A light emitting device comprising of:
a light emitting structure having an active region sandwiched between a plurality of layers of the first type and a plurality of layers of the second type;
a p-n junction is formed at the interface between the two types of layers and electron-hole injection is provided by applying a sufficiently large forward bias at the electrical terminals to the first and the second types;
a substrate that is on one side of the said light emitting structure;
a plurality of layers processed into a geometrical shaped extraction structure;
the said extraction structure is formed either on the exit surface or between the said active region and the exit surface.

2. The said extraction structure in claim 1 is either protrusion out of the layer or an indentation into the layer.

3. The said geometrical shapes in claims 1 are distributed orderly or randomly over the surface of the said extraction structure.

4. The geometrical shapes of the said extraction structure in claim 1 are produced or induced using lithography techniques.

5. The profile of the said geometrically shapes in claim 4 wherein is produced by transferring the thickness profile of a photoresist pattern into the extraction layer using a process such as dry etch process.

6. The shape profile of the said photoresist resist pattern in claim 5 is defined by using photolithography and subsequently a photoresist reflow process in which the edges of a photoresist pattern is gradually thinner than the center.

7. The shape profile of the said photoresist resist pattern in claim 5 is defined by using a gray scale photo mask in which the exposure dosage varies depending on the gray scale, resulting in a thickness profile during photoresist development.

8. The device in claim 1, wherein said substrate is a semiconductor material, including but not limited to, sapphire, SiC, GaN, AlN, ZnO, GaP, Si, Ge.

9. The device in claim 1, wherein said substrate is a non-semiconductor material, including but not limited to, glass, quartz, steel, aluminum.

10. The said extraction structure in claim 1 is formed between the active region and the exit surface by a conformal growth process starting from a pre-patterned substrate.
